(19) United States
(12) Patent Application Publication
(10) Pub. No.: US 2026/0198237 A1
(43) Pub. Date: Jul. 9, 2026

(54) METHOD AND DEVICE FOR FILLING MICROSTRUCTURED TRENCH OF SEMICONDUCTOR WITH NEUTRON CONVERSION MATERIAL

(71) Applicants: Shenzhen University, Shenzhen (CN); Nuclear Power Institute of China, Chengdu (CN)

(72) Inventors: Qiang YAN, Shenzhen (CN); Chuyuan MAO, Shenzhen (CN); Wenhua YANG, Chengdu (CN); Haitao ZHANG, Shenzhen (CN); Guoqing LIU, Shenzhen (CN); Zhengxin WU, Shenzhen (CN); Wei ZHU, Chengdu (CN); Liang ZHANG, Chengdu (CN)

(73) Assignees: Shenzhen University, Shenzhen, GD (CN); Nuclear Power Institute of China, Chengdu, SC (CN)

(21) Appl. No.: 19/326,523

(22) Filed: Sep. 11, 2025

(30) Foreign Application Priority Data
Jan. 9, 2025 (CN) 202510031883.0

(51) Int. Cl. H01L 21/02; G01T 3/08; H01L 21/677

(52) U.S. Cl. CPC H10P 14/6342; G01T 3/08; H10P 14/6528; H10P 14/6939; H10P 72/3312

(57) ABSTRACT

Provided is a method for filling a microstructured trench of a semiconductor with a neutron conversion material. including: fixing the semiconductor with the microstructured trench inside a centrifugal container, adding a LiF colloidal solution into the centrifugal container, and performing centrifugation to obtain the semiconductor with the microstructured trench filled with the neutron conversion material. Provided is a device for filling a microstructured trench of a semiconductor with a neutron conversion material, including: a semiconductor loader and a support frame that supports the semiconductor loader.

### CROSS-REFERENCE TO RELATED APPLICATION

This patent application claims the benefit and priority of Chinese Patent Application No. 202510031883.0 filed with the China National Intellectual Property Administration on Jan. 9, 2025, the disclosure of which is incorporated by reference herein in its entirety as part of the present application.

### TECHNICAL FIELD

The present disclosure relates to the field of semiconductor technologies, and in particular to a method and device for filling a microstructured trench of a semiconductor with a neutron conversion material.

### BACKGROUND

The Neutron, a neutral nucleon within the atomic nucleus, can be released through special nuclear reactions, and plays an important role in nuclear technology applications, nuclear energy engineering, and scientific research. A neutron detector is a radiation detector sensitive to neutrons and used for measuring physical parameters of neutrons. The performance of the neutron detector is closely related to the nuclear interactions between neutrons and their conversion material, and the magnitude of these interactions physically defines the upper limit of neutron detection efficiency. Among these detectors, a microstructured semiconductor neutron detector (MSND), based on the existing semiconductor processing technology, has the advantages of mature industrial chain, pure solid-state device, compact size, high detection efficiency, and easiness in integration, Consequently, the MSND has become the research focus of a solid-state neutron detector.

The prominent characteristics of the microstructured semiconductor neutron detector lies in that microstructured trenches are formed on a semiconductor, and filled with a neutron conversion material (generally lithium fluoride, LiF). In one aspect, the microstructured trenches greatly increases the filling volume of the neutron conversion material, which is beneficial to improving the neutron interaction probability and the generation probability of secondary charged particles. In another aspect, the microstructured trenches are typically only dozens of micrometers deep, allowing the secondary charged particles to easily travel through the conversion material to reach a silicon detector, which significantly reduces the self-absorption effect of the conversion material on the charged particles improving the detection efficiency for the charged particles. These two aspects above technically ensure the excellent detection performance of the microstructured neutron detector. The research and development of this type detector includes two core processes: creating trenches with required specifications (width, depth, and surface quality) using etching techniques to meet the design criteria; and filling the trench with the neutron conversion material using a suitable method to achieve a good filling effect.

Conventional microstructure lithium fluoride filling techniques include magnetron sputtering, vapor deposition, mechanical pressing, ultrasonic vibration, low-pressure condensation, melting immersion. However, it has been proved that these techniques exhibit substantial limitations and fail to adequately meet the filling requirements for LiF within microstructures of the semiconductor. Mechanical pressing and ultrasonic vibration belong to techniques that utilize external forces to press materials into microstructured trenches, and have the primary problems: 1) Non-uniform filling; 2) Operational challenges as a microstructured feature is a dozen microns; and 3) Structural fragility of micro-machined silicon wafers, where applied external forces readily damage microstructures. Both magnetron sputtering and vapor deposition involve decomposing lithium fluoride targets followed by material deposition onto surfaces, and have the primary problems: 1) Suitable only for surface treatments, lithium fluoride accumulates on the surface of the silicon wafer and cannot be filled into the microstructured trench; 2) Decomposed lithium fluoride exhibits strong corrosiveness, causing severe contamination and corrosion to equipment (e.g., vacuum chambers, pipelines, valves); and 3) Low process efficiency and poor material utilization efficiency. Both low-pressure condensation and melting immersion require first heating lithium fluoride to its molten state. In low-pressure condensation, the silicon wafer is positioned above lithium fluoride vapor, allowing LiF to deposit via condensation. Melting immersion directly submerges the silicon wafer into liquid lithium fluoride. These two methods have the following problems: 1) High-temperature operation: operating at lithium fluoride's melting point (870° C.) causes irreversible damage to the silicon wafer, affecting the electrical performance of the silicon wafer; 2) Ineffective trench filling: condensed lithium fluoride is of a fluffy structure and gathers on the surface of the silicon wafer, and there is essentially no lithium fluoride inside the trenches; 3) Ineffective trench filling: due to lithium fluoride melt's non-wetting behavior to the silicon wafer, the microstructured trenches fail to be infiltrated, where lithium fluoride melt only gathers on the surfaces of the trenches in practice; and 4) Thermal stress collapse: due to rapid thermal cycling in the operation process, thermal stress causes the microstructure of the silicon wafer to collapse, preventing process implementation.

### SUMMARY

In view of this, an objective of the present disclosure is to provide a method and device for filling a microstructured trench of a semiconductor with a neutron conversion material. The method and the device provided by the present disclosure can realize dense and complete filling of the neutron conversion material, i.e., lithium fluoride, in the microstructure without destroy the microstructure of the semiconductor, to meet technological requirements of an MSND chip.

In order to achieve the above objective, the present disclosure provides the following technical solutions.

The present disclosure provides a method for filling a microstructured trench of a semiconductor with a neutron conversion material, including:
fixing the semiconductor with the microstructured trench inside a centrifugal container, adding a LiF colloidal solution into the centrifugal container, and performing centrifugation to obtain the semiconductor with the microstructured trench filled with the neutron conversion material.

Preferably, the semiconductor is a silicon-based semiconductor; and the microstructured trench has a width of 15 μm-30 μm.

Preferably, a process for preparing the LiF colloidal solution comprises:
ultrasonically mixing LiF nano-powder with an alcohol solvent to obtain the LiF colloidal solution, the LiF nano-powder having a particle size of 200 nm-400 nm.

Preferably, the LiF colloidal solution has a mass concentration of 2‰-1%.

Preferably, the centrifugation is horizontal centrifugation, and the centrifugation is performed at a rate of 3,000 rpm-4,000 rpm for 8 min-15 min.

Preferably, the method further includes:
after the centrifugation, transferring the semiconductor with the microstructured trench filled with the neutron conversion material into an alcoholic solvent, and performing ultrasonic treatment to remove excess LiF from a surface of the semiconductor.

Preferably, the method further includes:
after the centrifugation, repeating mixing-centrifugation operations of the LiF colloidal solution and the semiconductor with the microstructured trench filled with the neutron conversion material.

The present disclosure provides a device for filling a microstructured trench of a semiconductor with a neutron conversion material, including: a semiconductor loader, where a surface of the semiconductor loader is provided with a loading groove, a surface of the loading groove contains an electrostatic self-adhesive film, and an edge of the semiconductor loader is provided with a limiting notch; and
a support frame that supports the semiconductor loader, wherein the support frame comprises a bottom tray and a stand column vertically arranged on an edge of the bottom tray, and a width of the stand column matches a size of the limiting notch of the semiconductor loader.

Preferably, the electrostatic self-adhesive film is made from polyethylene and has a thickness of 0.1 mm-0.2 mm.

Preferably, the bottom tray is made of a matte-finish material.

The present disclosure provides the method for filling a microstructured trench of a semiconductor with a neutron conversion material, including: fixing the semiconductor with the microstructured trench inside a centrifugal container, adding a LiF colloidal solution into the centrifugal container, and performing centrifugation to obtain the semiconductor with the microstructured trench filled with the neutron conversion material. The present disclosure employs a wet centrifugal cold-process route to fill the microstructure with a LiF colloidal particles in a centrifugal manner without heating the semiconductor. Under centrifugal force, the microstructure is compactly and completely filled with lithium fluoride, which meets the technological requirements of the MSND chip and solves limitations of alternative methods.

Furthermore, according to the present disclosure, a high power optical microscope is used to examine whether there is deposition accumulation on a surface of the semiconductor. If the deposition accumulation is significant, the lithium fluoride particles deposited on the surface can be removed by means of ultrasonic vibration. In addition, multiple cycles of centrifugal fillings can be performed based on the total amount of lithium fluoride required to be filled and the mass of lithium fluoride filled per cycle.

The present disclosure provides the device for filling a microstructured trench of a semiconductor with a neutron conversion material, including the semiconductor loader and the support frame that supports the semiconductor loader. In the present disclosure, the semiconductor with the microstructured trench may be fixed to the surface of the semiconductor loader through the electrostatic self-adhesive film, which can prevent the semiconductor substrate from rolling over or displacement caused by flowing of the solution since the semiconductor substrate itself is low in density and small in size; and the semiconductor loader is provided with the limiting notch, and the limiting notch matches the stand column of the support frame to realize fixing of the semiconductor loader, such that the semiconductor loader is prevented from rotating or rolling over, and the semiconductor loader can be conveniently installed and detached through the support frame. Furthermore, the tray of the support frame is made of a matte-finish material, which can effectively prevent the semiconductor loader from adhering to the tray or the bottom of the centrifugal container due to liquid tension.

### BRIEF DESCRIPTION OF THE DRAWINGS

FIG. 1 is a schematic diagram of assembly of a semiconductor loader 1;

FIG. 2 is a schematic diagram of assembly of a semiconductor 3, the semiconductor loader 1 and the electrostatic self-adhesive film 2;

FIG. 3 is a schematic structural diagram of a support frame 4;

FIG. 4 is a schematic diagram of assembly of the semiconductor loader 1 and the support frame 4;

FIG. 5 is a schematic diagram of an overall structure of an assembled flat-bottomed centrifugal tube;

FIG. 6 is a schematic cross-sectional view of the assembled flat-bottomed centrifugal tube;

FIG. 7 is an SEM image of a filled silicon wafer of Example 1;

FIG. 8 is an SEM image of a filled silicon wafer of Example 2; and

FIG. 9 is an SEM image of a filled silicon wafer of Example 3.

### DETAILED DESCRIPTION OF THE EMBODIMENTS

The present disclosure provides a method for filling a microstructured trench of a semiconductor with a neutron conversion material, including:
the semiconductor with the microstructured trench is fixed inside a centrifugal container, a LiF colloidal solution is added into the centrifugal container, and centrifugation is performed to obtain the semiconductor with the microstructured trench filled with the neutron conversion material.

In the present disclosure, the semiconductor is preferably a silicon-based semiconductor, more preferably a silicon wafer. In the present disclosure, the microstructured trench has a width of preferably 15 μm-30 μm. As a specific implementation of the present disclosure, the microstructured trench has a width of 15 μm, 20 μm, 25 μm or 30 μm.

In the present disclosure, that centrifugal container is preferably a centrifugal tube, more preferably a flat-bottomed centrifugal tube.

In the present disclosure, a mass concentration of the LiF colloidal solution is preferably 2‰-1%, further preferably 0.4%-0.8%. As a specific implementation of the present disclosure, a mass concentration of the LiF colloidal solution is preferably 0.2%, 0.4%, 0.5%, 0.6%, 0.8%, 1%.

In the present disclosure, a process for preparing the LiF colloidal solution preferably includes:
LiF nano-powder is ultrasonically mixed with an alcohol solvent to obtain the LiF colloidal solution.

In the present disclosure, the LiF nano-powder has a particle size of preferably 200 nm-400 nm. In the present disclosure, the alcohol solvent is preferably absolute ethanol and/or isopropanol.

In the present disclosure, the ultrasonic mixing is performed at a power of preferably 500 W-1,000 W, more preferably 700 W-800 W, for preferably 8 min-30 min, more preferably 8 min-15 min.

According to the present disclosure, after the ultrasonic mixing, the resulting LiF colloidal solution is preferably transferred into a rotor stirrer for continuous stirring for later use.

In the present disclosure, the centrifugation is preferably horizontal centrifugation. In the present disclosure, the centrifugation is preferably high-speed centrifugation; and the centrifugation is performed at a rate of preferably 3,000 rpm-4,000 rpm for preferably 8 min-15 min, more preferably 10 min. According to the present disclosure, the centrifugation is preferably performed using a horizontal centrifuge equipped with a horizontal rotor. As a specific embodiment of the present disclosure, a model of the centrifuge is TDL-5A. In the present disclosure, the semiconductor with the microstructured trench is preferably fixed to a bottom of the centrifugal container, the centrifugal container is placed horizontally during centrifugation, the bottom of the centrifugal container is located away from the center of the centrifuge, and the microstructured trench is filled with lithium fluoride under the action of a centrifugal force.

According to the present disclosure, after centrifugation, a high power optical microscope is preferably used to examine whether there is deposition accumulation on a surface of the semiconductor. If the deposition accumulation is significant, the method further includes: the semiconductor with the microstructured trench filled with the neutron conversion material is transferred into an alcoholic solvent for ultrasonic treatment to remove excess LiF from the surface of the semiconductor.

In the present disclosure, the alcohol solvent is preferably absolute ethanol. In the present disclosure, the ultrasonic treatment is performed for preferably 8 s-10 s at a power of preferably 500 W-1,000 W, more preferably 760 W and at a frequency of preferably 40 kHz. According to the present disclosure, the lithium fluoride particles deposited on the surface are removed by means of short-time ultrasonic vibration.

According to the present disclosure, after centrifugation, the number of cycles of centrifugal fillings to be performed is calculated based on the total amount of lithium fluoride required to be filled and the mass of lithium fluoride filled per cycle. In the present disclosure, the multiple cycles of centrifugal filling specifically include: mixing-centrifugation operations of the LiF colloidal solution and the semiconductor with the microstructured trench filled with the neutron conversion material are repeated. The present disclosure has no special requirements on the number of the repetitions as long as corresponding calculations are made according to the total amount of lithium fluoride required to be filled and the mass of lithium fluoride filled per repetition. As a specific implementation of the present disclosure, the number of the repetitions is 1, 2 or 3.

In the present disclosure, the specific processes of preparation and centrifugation of the LiF colloidal solution are the same as those described above and hence will not be repeated herein.

According to the present disclosure, after centrifugation, the resulting semiconductor with the microstructured trench filled with the neutron conversion material is preferably dried. In the present disclosure, the drying is preferably baking.

The present disclosure provides a device for filling a microstructured trench of a semiconductor with a neutron conversion material, including: a semiconductor loader 1, where a surface of the semiconductor loader 1 is provided with a loading groove 11, a surface of the loading groove 11 is provided with an electrostatic self-adhesive film 2, and an edge of the semiconductor loader 1 is provided with a limiting notch 12; and
a support frame 4 that supports the semiconductor loader 1, where the support frame 4 includes a bottom tray 42 and a stand column 41 vertically provided on an edge of the bottom tray 42, and a width of the stand column 41 matches a size of a limiting notch of the semiconductor loader 1.

In the present disclosure, the loading groove 11 in the surface of the semiconductor loader 1 is preferably of a hollow structure, and the electrostatic self-adhesive film 2 is bonded onto a bottom surface of the semiconductor loader 1, so that the electrostatic self-adhesive film 2 is exposed on the surface of the loading groove 11.

In the present disclosure, the surface of the semiconductor loader 1 is preferably provided with one or more loading grooves 11, and the number of the loading grooves 11 ranges preferably from 1 to 4. In the present disclosure, the dimension of the individual loading groove 11 is preferably 1 (cm)×1 (cm). In the present disclosure, the semiconductor loader 1 is in a shape preferably the same as that of a cross section of the centrifugal container and is of a size slightly smaller than that of the cross section of the centrifugal container 5. The present disclosure has no special requirements on the material of the semiconductor loader 1.

In the present disclosure, the electrostatic self-adhesive film 2 is preferably made from polyethylene and has a thickness of preferably 0.1 mm-0.2 mm, more preferably 0.1 mm.

In the present disclosure, the dimension of the bottom tray 42 is preferably the same as that of the semiconductor loader 1. In the present disclosure, the bottom tray 42 is preferably made of a matte-finish material. As a specific embodiment of the present disclosure, the bottom tray 42 is made of aluminum alloy having an surface roughness Ra of preferably 1.5 μm-3 μm.

In the present disclosure, the number of the stand columns 41 is preferably 2-4; and height of each stand column 41 is preferably the same as a height of the centrifugal container.

In the present disclosure, a fixing structure 43 is further preferably arranged on a top of the stand column 41 for connecting and fixing the multiple stand columns 41 while facilitating gripping for installation and unloading.

In the present disclosure, the device for filling a microstructure trench of a semiconductor with a neutron converting material further preferably includes a centrifugal container 5, and the centrifugal container 5 is preferably a flat-bottomed centrifugal tube. In the present disclosure, when the microstructured trench of the semiconductor is filled with the neutron conversion material, the semiconductor 3 is bonded to the surface of the loading groove 11 of the semiconductor loader 1 by the electrostatic self-adhesive film 2, and the semiconductor loader 1 loaded with the semiconductor 3 is in snap fit with the stand columns 41 through the limiting notches 12, to be fixed to the surface of the bottom tray 42 of the support frame 4. The semiconductor loader 1 and the support frame 4 that are assembled are placed in the centrifugal container 5 for centrifugation.

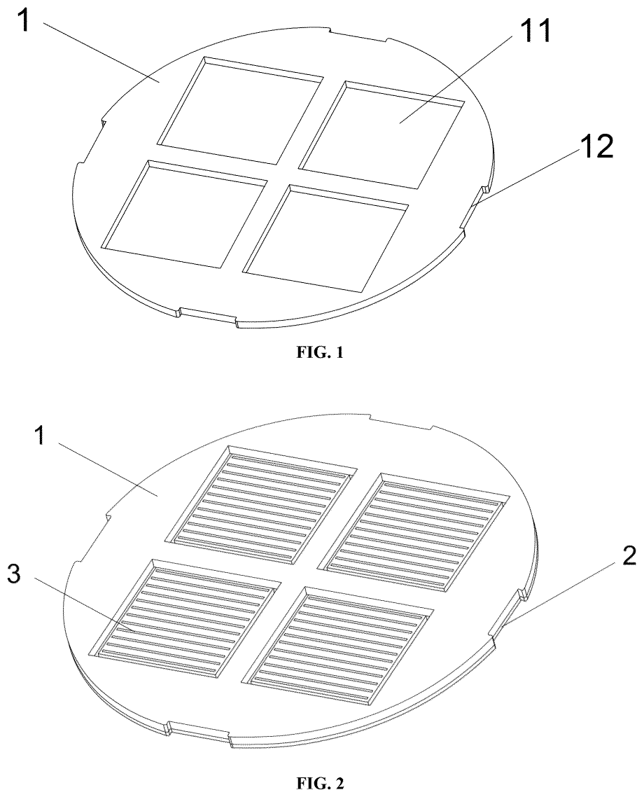

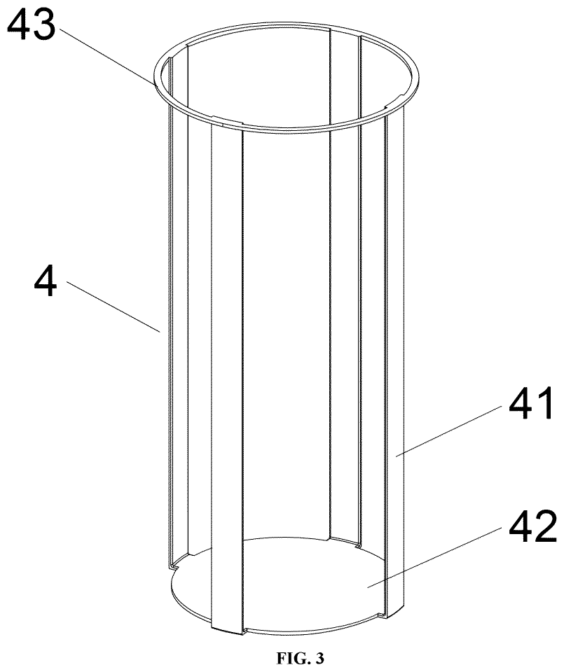

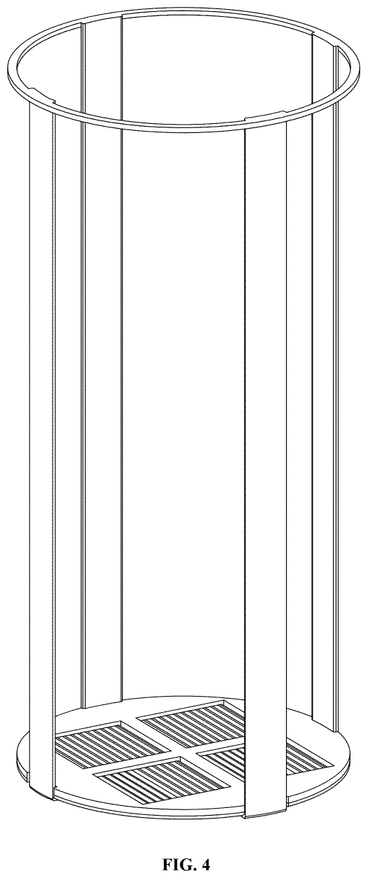

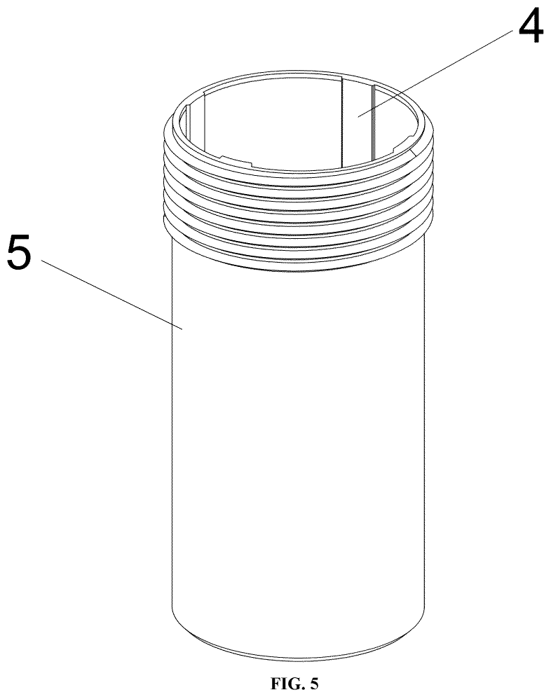

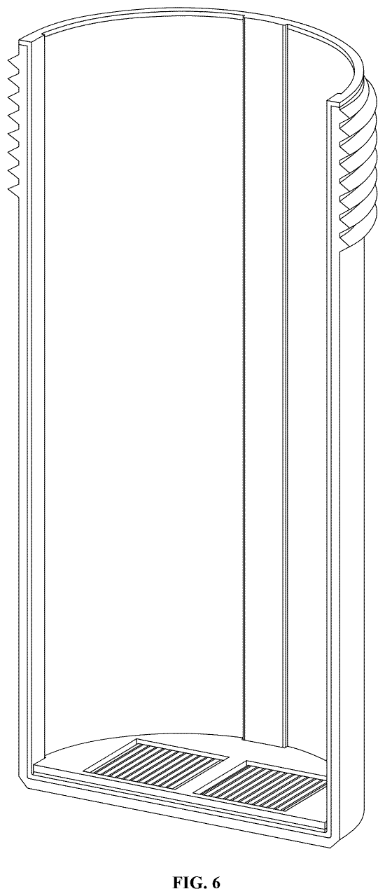

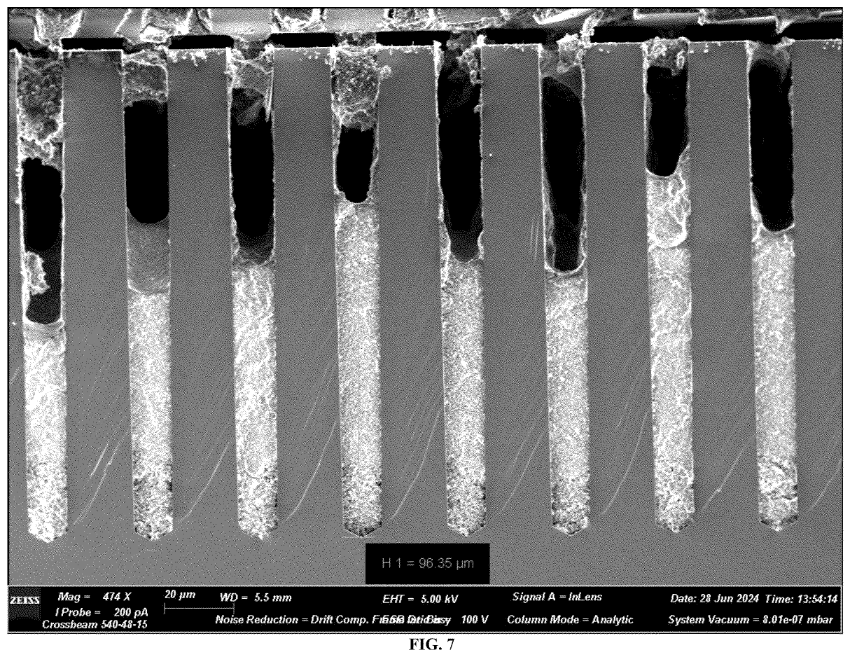

As a specific implementation of the present disclosure, a schematic diagram of the semiconductor loader 1 is shown in FIG. 1; a schematic diagram of assembly of the semiconductor 3, the semiconductor loader 1 and the electrostatic self-adhesive film 2 is shown in FIG. 2; a schematic structural diagram of the support frame 4 is shown in FIG. 3; a schematic diagram of assembly of the semiconductor loader 1 and the support frame 4 is shown in FIG. 4; a schematic diagram of an overall structure of the assembled flat-bottomed centrifugal tube is shown in FIG. 5; and a schematic cross-sectional view of the assembled flat-bottomed centrifugal tube is shown in FIG. 6. In FIGS. 1-6 , reference numeral 1 indicates the semiconductor loader, reference numeral 2 indicates the electrostatic self-adhesive film, reference numeral 3 indicates the semiconductor, reference numeral 4 indicates the support frame, reference numeral 5 indicates the centrifugal container, reference numeral 11 indicates the loading groove, reference numeral 12 indicates the limiting notch, reference numeral 41 indicates the stand column, reference numeral 42 indicates the bottom tray, and reference numeral 43 indicates the fixing structure.

The method and device for filling a microstructured trench of a semiconductor with a neutron conversion material provided by the present disclosure will be described in detail below with reference to examples, but these examples should not be construed as limiting the scope of protection of the present disclosure.

### Example 1

A silicon wafer was taken as a semiconductor material, and a semiconductor loader was correspondingly a silicon wafer loader.

The loading procedure of the silicon wafer was as follows: an electrostatic self-adhesive film 2 was bonded to a bottom surface of the semiconductor loader 1, confirming the absence of air bubble at the bonding interface, a silicon wafer (a semiconductor 3) was gently placed into a loading groove 11, a silicon wafer loader obtained in the above steps was snapped into the stand columns 41 around the support frame 4 through limiting notches 12, and placed on the bottom tray 42 of the support frame 4, and the support frame 4 obtained in the above steps was placed in a flat-bottomed centrifugal tube (a centrifugal container 5) to obtain the flat-bottomed centrifugal tube loaded with the silicon wafer.

The Filling procedure of LiF powder was as follows:
1) preparation of a LiF colloidal solution: 100 parts of a main material, i.e., absolute ethanol were injected into a clean beaker, 0.2 part of LiF nano-powder with a particle size of 200 nm-400 nm was added, the beaker was sealed and placed in an ultrasonic water bath, the ultrasonic vibration was performed at 750 W for 30 min, the ultrasonic vibration is stopped until there was no obvious particle agglomeration in the solution to obtain a LiF colloidal solution, and the LiF colloidal solution was transferred into a rotor stirrer for continuous stirring for later use;
2) high-speed centrifugation: 50 g of the above LiF colloidal solution was transferred into a flat-bottomed centrifugal tube, the flat-bottomed centrifugal tube was transferred into a centrifuge, a rotational speed of centrifugation of the centrifuge was set to 4,000 rpm and time of centrifugation of the centrifuge was set to 10 min, and a centrifugation operation by the centrifuge is completely finished to obtain an initially filled silicon wafer;
3) ultrasonic cleaning: 10 parts of absolute ethanol was injected into a clean beaker, the above initially filled silicon wafer was transferred to the absolute ethanol, the beaker was placed into the ultrasonic water bath, and ultrasonic vibration was performed for 10 s at an ultrasonic power of 760 W and a frequency of 40 kH to remove LiF particles deposited on the surface of the silicon wafer; and
4) natural drying: the silicon wafer was taken out after the ultrasonic cleaning is completed, and the silicon wafer was placed in a dryer for natural drying to obtain a finally filled silicon wafer.

### Example 2

A silicon wafer was loaded as in Example 1.

The Filling procedure of LiF powder was as follows:
1) preparation of a LiF colloidal solution: 100 parts of a main material, i.e., absolute ethanol, were injected into a clean beaker, 0.5 part of LiF nano-powder with a particle size of 200 nm-400 nm was added, the beaker was sealed and placed in an ultrasonic water bath, the ultrasonic vibration was performed at 750 W for 30 min, the ultrasonic vibration is stopped until there was no obvious particle agglomeration in the solution to obtain a LiF colloidal solution, and the LiF colloidal solution was transferred into a rotor stirrer for continuous stirring for later use;
2) high-speed centrifugation: 50 g of the above LiF colloidal solution was transferred into a flat-bottomed centrifugal tube, the flat-bottomed centrifugal tube was transferred into a centrifuge, a rotational speed of centrifugation of the centrifuge was set to 4,000 rpm and time of centrifugation of the centrifuge was set to 10 min, and a centrifugation operation by the centrifuge is completely finished to obtain an initially filled silicon wafer;
3) ultrasonic cleaning: 10 parts of absolute ethanol was injected into a clean beaker, the above initially filled silicon wafer was transferred to the absolute ethanol, the beaker was placed into the ultrasonic water bath, and ultrasonic vibration was performed for 10 s at an ultrasonic power of 760 W and a frequency of 40 kH to remove LiF particles deposited on the surface of the silicon wafer; and
4) natural drying: the silicon wafer was taken out after the ultrasonic cleaning is completed, and the silicon wafer was placed in a dryer for natural drying to obtain a finally filled silicon wafer.

### Example 3

A silicon wafer was loaded as in Example 1.

The Filling procedure of LiF powder was as follows:
1) preparation of a LiF colloidal solution: 100 parts of a main material, i.e., absolute ethanol, were injected into a clean beaker, 1 part of LiF nano-powder with a particle size of 200 nm-400 nm was added, the beaker was sealed and placed in an ultrasonic water bath, the ultrasonic vibration was performed at 750 W for 30 min, the ultrasonic vibration is stopped until there was no obvious particle agglomeration in the solution to obtain a LiF colloidal solution, and the LiF colloidal solution was transferred into a rotor stirrer for continuous stirring for later use;
2) high-speed centrifugation: 50 g of the above LiF colloidal solution was transferred into a flat-bottomed centrifugal tube, the flat-bottomed centrifugal tube was transferred into a centrifuge, a rotational speed of centrifugation of the centrifuge was set to 4,000 rpm and time of centrifugation of the centrifuge was set to 10 min, and a centrifugation operation by the centrifuge is completely finished to obtain an initially filled silicon wafer;
3) ultrasonic cleaning: 10 parts of absolute ethanol was injected into a clean beaker, the above initially filled silicon wafer was transferred to the absolute ethanol, the beaker was placed into the ultrasonic water bath, and ultrasonic vibration was performed for 10 s to remove LiF particles deposited on the surface of the silicon wafer; and
4) natural drying: the silicon wafer was taken out after the ultrasonic cleaning is completed, and the silicon wafer was placed in a dryer for natural drying to obtain a finally filled silicon wafer.

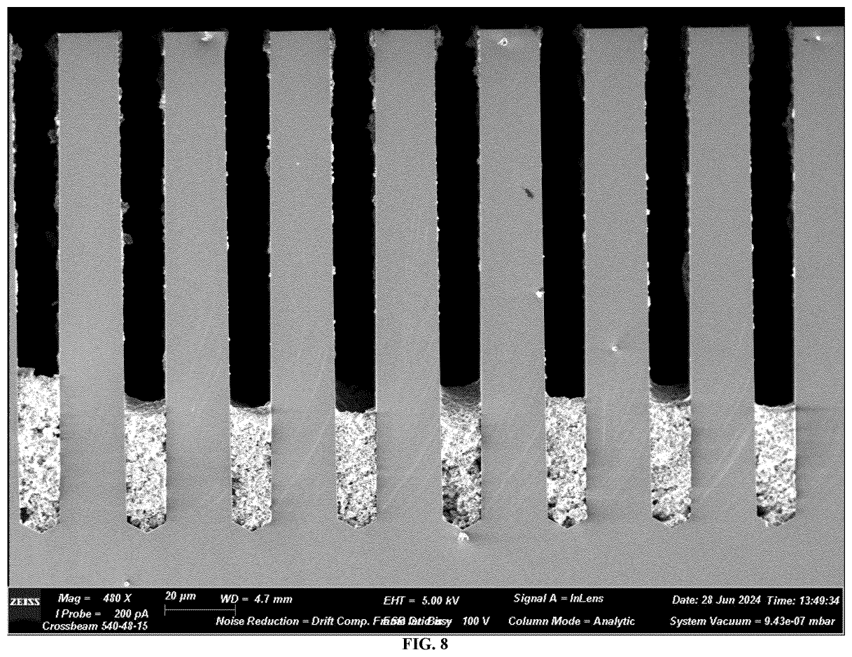

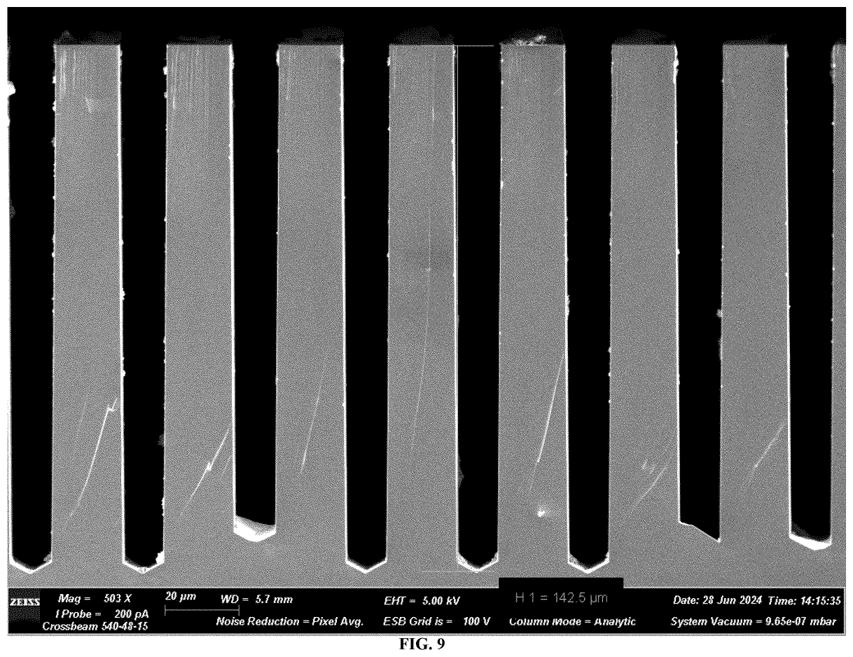

The finally filled silicon wafer was placed under an optical microscope for observation. With the eyepiece magnification fixed at 10×, the deposition on the wafer surface was examined at magnifications of 10×, 20×, and 50×. Subsequently, the silicon wafer was split along the perpendicular direction of the etched grooves using the cleavage method. A scanning electron microscope (SEM) is employed to observe the cross-sectional profile of the etched grooves, assessing key parameters such as LiF filling amount, filling uniformity, and filling density. An SEM image of the finally filled silicon wafer in Example 1 is shown in FIG. 7, an SEM image of the finally filled silicon wafer in Example 2 is shown in FIG. 8, and an SEM image of the finally filled silicon wafer in Example 3 is shown in FIG. 9.

In Example 1, the mass density of the LiF colloidal solution is two thousandths, and an observation of the cross-sectional profile of the silicon wafer through the SEM shows that LiF was compactly filled with a good filling effect, a filling amount of about 50% and better filling uniformity.

In Example 2, the mass density of the LiF colloidal solution is five thousandths, and an observation of the cross-sectional profile of the silicon wafer through the SEM shows that LiF was compactly filled with a good filling effect, a filling amount of about 20% and good filling uniformity.

In Example 3, the mass density of the LiF colloidal solution is one hundredth, and an observation of the cross-sectional profile of the silicon wafer through the SEM shows that the filling effect of LiF is poor, the filling amount of LiF is about 2% and the filling uniformity of LiF is moderate.

The descriptions above are merely the preferred embodiments of the present disclosure. It should be noted that several improvements and modifications may also be made by those of ordinary skill in the art without departing from the principle of the present disclosure, and these improvements and modifications should also be considered within the protection scope of the present disclosure.

What is claimed is:

1. A method for filling a microstructured trench of a semiconductor with a neutron conversion material, comprising:
fixing the semiconductor with the microstructured trench inside a centrifugal container,
adding a LiF colloidal solution into the centrifugal container, and
performing centrifugation to obtain the semiconductor with the microstructured trench filled with the neutron conversion material.

2. The method according to claim 1, wherein the semiconductor is a silicon-based semiconductor; and the microstructured trench has a width of 15 μm-30 μm.

3. The method according to claim 1, wherein a process for preparing the LiF colloidal solution comprises:
ultrasonically mixing LiF nano-powder with an alcohol solvent to obtain the LiF colloidal solution,
the LiF nano-powder having a particle size of 200 nm-400 nm.

4. The method according to claim 1, wherein the LiF colloidal solution has a mass concentration of 2‰-1%.

5. The method according to claim 1, wherein the centrifugation is horizontal centrifugation, and the centrifugation is performed at a rate of 3,000 rpm-4,000 rpm for 8 min-15 min.

6. The method according to claim 1, further comprising:
after the centrifugation, transferring the semiconductor with the microstructured trench filled with the neutron conversion material into an alcoholic solvent, and performing ultrasonic treatment to remove excess LiF from a surface of the semiconductor.

7. The method according to claim 1, further comprising:
after the centrifugation, repeating mixing-centrifugation operations of the LiF colloidal solution and the semiconductor with the microstructured trench filled with the neutron conversion material.

8. A device for filling a microstructured trench of a semiconductor with a neutron conversion material, comprising:
a semiconductor loader (1), wherein a surface of the semiconductor loader (1) is provided with a loading groove (11), a surface of the loading groove (11) contains an electrostatic self-adhesive film (2), and an edge of the semiconductor loader (1) is provided with a limiting notch (12); and
a support frame (4) that supports the semiconductor loader (1), wherein the support frame (4) comprises a bottom tray (42) and a stand column (41) vertically arranged on an edge of the bottom tray (42), and a width of the stand column (41) matches a size of the limiting notch of the semiconductor loader (1).

9. The device according to claim 8, wherein the electrostatic self-adhesive film (2) is made from polyethylene and has a thickness of 0.1 mm-0.2 mm.

10. The device according to claim 8, wherein the bottom tray (42) is made of a matte-finish material.

11. The method according to claim 3, wherein the LiF colloidal solution has a mass concentration of 2‰-1%.
